(19) United States
(12) Patent Application Publication
(10) Pub. No.: US 2011/0260593 A1
(43) Pub. Date: Oct. 27, 2011

(54) SERVER CABINET WITH DUAL-FUNCTION SIDE DOOR

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 12/813,529

(22) Filed: Jun. 11, 2010

(30) Foreign Application Priority Data
Apr. 21, 2010 (TW) 99112565

(51) Int. Cl. H05K 5/02; A47B 96/00

(52) U.S. Cl. 312/293.3

(57) ABSTRACT

An exemplary server cabinet includes a rack and a side door detachably connected with the rack. The rack includes a top wall, an opposite bottom wall, and sidewalls connected between the top and bottom walls. The rack is adapted to accommodate a plurality of servers. The side door includes a reinforcing brace such that when the rack is fully loaded with the servers and the side door is detached from the rack and positioned at an oblique angle between two surfaces capable of supporting the fully loaded server cabinet, the fully loaded server cabinet can be moved along the side door between the two surfaces.

### BACKGROUND

1. Technical Field

The present disclosure relates to a server cabinet with a side door to provide convenient transportation for the server cabinet when the server cabinet has servers installed therein.

2. Description of Related Art

Computer server systems often include multiple standard servers mounted in a standard server cabinet. Each server is a stand-alone computer that can include many electric components, such as one or more processors, RAM (random access memory), fixed disks, AC to DC power supplies, and the like. For unified management, the servers are arranged in the server cabinet one-by-one from bottom to top. A common computer server system with the servers installed in the server cabinet has a weight of about 200 kilograms.

During shipment of the computer server system, the computer server system is mounted on a stack board (or pallet). When the computer server system reaches a destination, a guiding ramp is provided. The guiding ramp is arranged between the stack board and the ground, and is typically gently sloped in this position. The computer server system can be moved from the stack board to the guiding ramp, and then slid or wheeled down the guiding ramp to the ground. However, each computer server system needs such a guiding ramp for shipment to a destination, and the guiding ramp is usually metal and discarded after the computer server system has been moved from the stack board to the ground. Therefore the need for the guiding ramp increases the cost of shipment of the computer server system, and generates waste material.

It is thus desirable to provide a server cabinet with means which can overcome the described limitations.

### BRIEF DESCRIPTION OF THE DRAWINGS

FIG. 1 is an isometric, assembled view of a computer server system in accordance with an exemplary embodiment of the present disclosure, the computer server system comprising a server cabinet, the server cabinet comprising a rack and a side door; and showing the computer server system mounted on a stack board.

FIG. 2 is similar to FIG. 1, but shows the side door detached from the rack and positioned between the stack board and the ground as a ramp.

FIG. 3 is an enlarged, isometric view showing complementary locking mechanisms of the rack and the side door of the computer server system of FIG. 1.

FIG. 4 is an enlarged, isometric view of the side door of FIG. 1.

FIG. 5 is an exploded view of the side door of FIG. 4.

FIG. 6 is an enlarged, isometric view of a handle of the side door of FIG. 5.

FIG. 7 is a side view showing the computer server system of FIG. 2 being wheeled down the side door to the ground.

### DETAILED DESCRIPTION

Reference will now be made to the drawing figures to describe embodiments of the present server cabinet in detail.

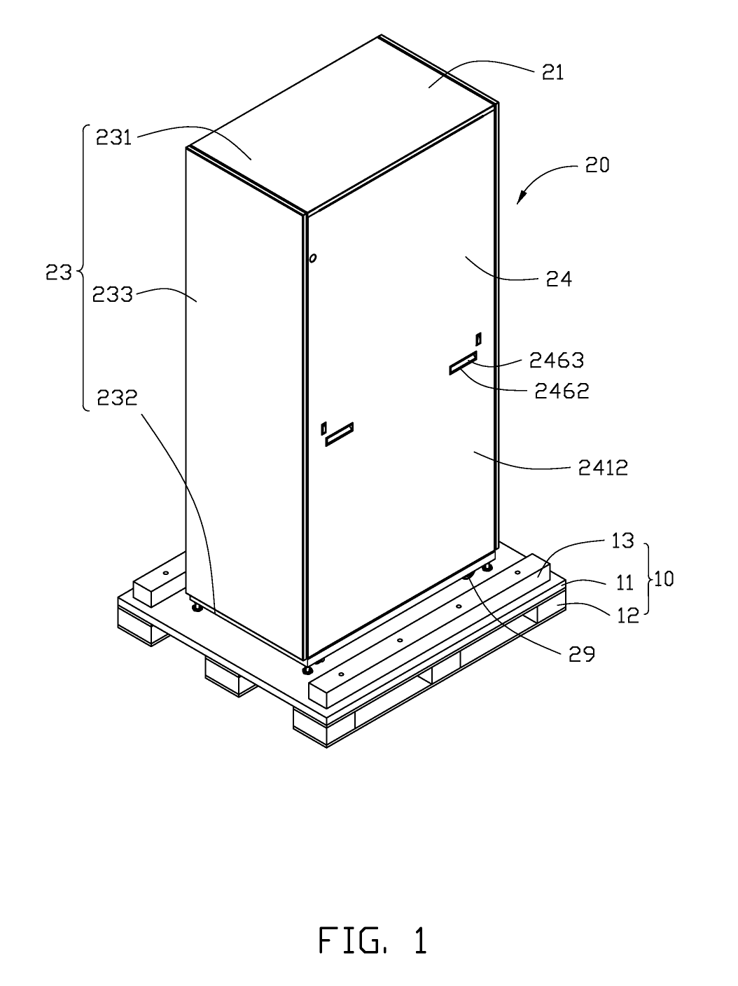

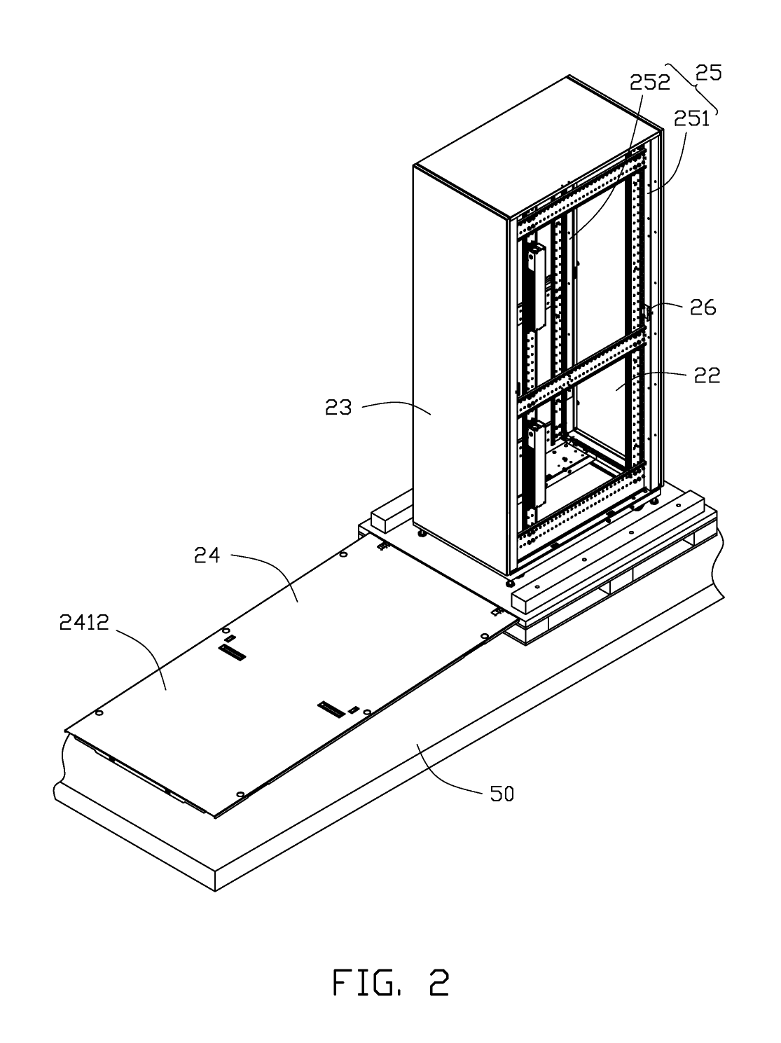

Referring to FIGS. 1 and 2, a computer server system 20 according to an exemplary embodiment of the present disclosure is shown. The computer server system 20 is mounted on a stack board (or pallet) 10 to satisfy shipment requirements. The computer server system 20 includes a server cabinet 21, and a plurality of servers (not shown) accommodated in the server cabinet 21. The computer server system 20 has a weight of about 200 kilograms.

The stack board 10 includes a supporting plate 11, a plurality of posts 12 depending perpendicularly from a bottom surface of the supporting plate 11, a plurality of elongated feet (not labeled) supporting the posts 12, and two elongated restraining blocks 13 extending perpendicularly upward from a top surface of the supporting plate 11. The supporting plate 11 is rectangular, and configured for supporting the computer server system 20 thereon. The restraining blocks 13 are located at two opposite sides of the top surface of the supporting plate 11, respectively. The computer server system 20 is positioned between the restraining blocks 13.

The server cabinet 21 includes a hollow cuboid rack 23, a supporting frame 25 received in the rack 23, and a side door 24 detachably mounted to one side of the rack 23. The rack 23 includes a rectangular top wall 231, a bottom wall 232 parallel to the top wall 231, and three sidewalls 233 respectively connected between left, rear and right sides of the top wall 231 and the bottom wall 232. The top wall 231, the bottom wall 232 and the sidewalls 233 cooperatively define a rectangular receiving space 22 receiving the servers therein. The side door 24 is detachably mounted between the front side of the top wall 231 and the bottom wall 232. Referring back to FIG. 1, four wheels 29 are provided on a bottom side of the bottom wall 232. The wheels 29 can for example be casters.

The supporting frame 25 includes two front supporting posts 251 and two rear supporting posts 252. When the supporting frame 25 is installed in the rack 23, the front supporting posts 251 are at a front side of the rack 23, and abut front ends of the two sidewalls 253 on the left and right sides of the rack 23, respectively. The rear supporting posts 252 are at the back of the rack 23, and abut rear ends of the two sidewalls 253 on the left and right sides of the rack 23, respectively. Heights of the front and rear supporting posts 251, 252 are substantially equal to those of the sidewalls 253. Each of the front and rear supporting posts 251, 252 is interconnected between the top and bottom walls 231, 232, with top and bottom ends of the front and rear supporting posts 251, 252 abutting the top and bottom walls 231, 232, respectively. The front supporting posts 231 are adjacent to left and right sides of the side door 24, respectively.

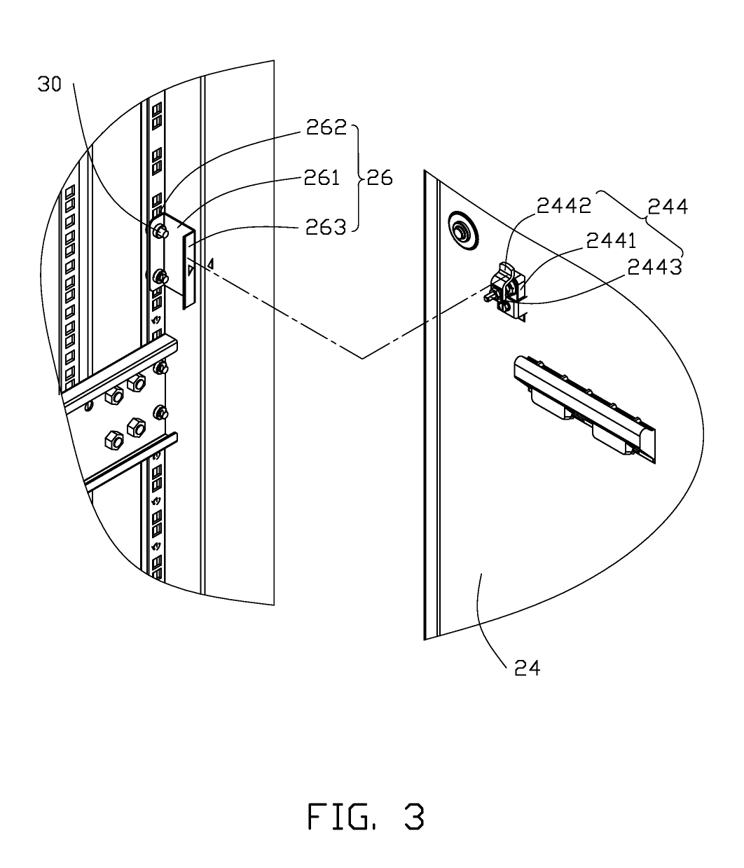

A latch hook 26 is mounted at a middle portion of each of the front supporting posts 251. Referring also to FIG. 3, the latch hook 26 is substantially U-shaped. The latch hook 26 includes a rectangular, plate-shaped main body 261, and a first flange 262 and a second flange 263 extending perpendicularly from two opposite sides of the main body 261, respectively. The first flange 262 is connected to the front supporting post 251 via bolts 30. The second flange 263 is adjacent to the side door 24.

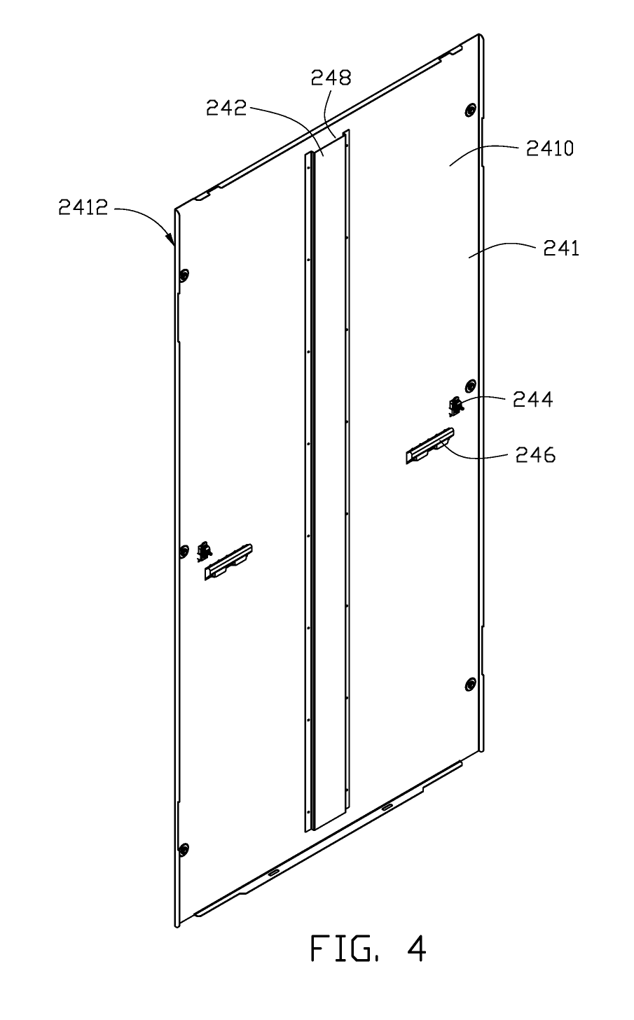

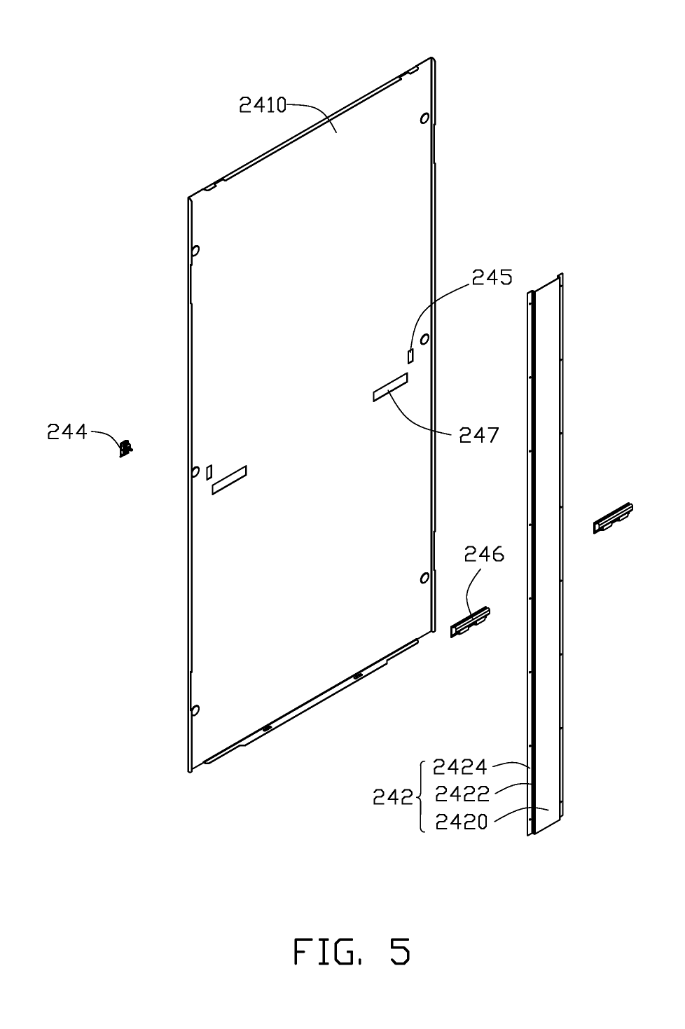

Referring to FIGS. 4 and 5 together, the side door 24 includes a rectangular main plate 241, a brace 242 located at a middle of the main plate 241, two fasteners 244 located at left and right sides of the main plate 241, respectively, and two handles 246 located adjacent to the fasteners 244, respectively. The main plate 241 includes an inner surface 2410 facing the rack 23 and an outer surface 2412. The main plate 241 is made of steel and has a thickness of about 1.2 mm (millimeters).

The fasteners 244 correspond to the latch hooks 26, respectively. Referring to FIG. 3 again, each of the fasteners 244 includes a mounting portion 2441 contacting the inner surface 2410 of the main plate 241, a shaft 2443 protruding outwardly from the mounting portion 2441, and a bent fastening catch 2442 mounted around the shaft 2443. The main plate 241 defines two rectangular through holes 245 at positions which correspond to the fasteners 244, respectively. When the fasteners 244 are assembled to the main plate 241, the mounting portions 2441 are connected with the inner surface 2410 of the main plate 241 and cover the through holes 245, respectively, the shaft 2443 extends inwardly towards an interior of the rack 23, and the fastenings strips 2442 face the latch hooks 26 on the supporting frame 25, respectively.

The shaft 2443 and the fastening catch 2442 of each fastener 244 are rotatable in unison with respect to the mounting portion 2441. Such rotation can be performed by accessing the shaft 2443 from a front side of the side door 24 via the through hole 245, using, e.g., a tool. Thus, the fastening catch 2442 can be rotated between a first position where the fastening catch 2442 is perpendicular to and engaged with the second flange 263, and a second position where the fastening catch 2442 is parallel to and disengaged from the second flange 263. When both the fastening catches 2442 are in the first position, the side door 24 and the rack 23 are fixed together. When both the fastening catches 2442 are in the second position, the side door 24 can be detached from the rack 23.

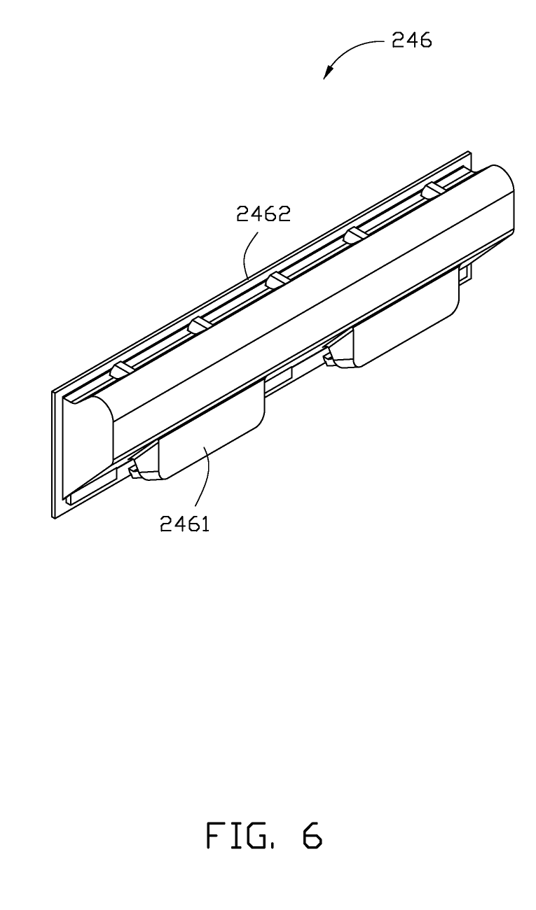

The main plate 241 defines two slots 247 corresponding to the handles 246, respectively. Referring also to FIG. 6, each of the handles 246 includes a bent, recessed holding portion 2461 having an opening 2463 at a front side thereof, and a frame-shaped flange 2462 extending around a periphery of the opening 2463. The opening 2463 is substantially the same size as that of the corresponding slots 247. When the handles 246 are attached to the main plate 241, the holding portions 2461 are recessed from the inner surface 2410 of the main plate 241, with the openings 2463 aligned with and communicated with the slots 247, respectively (see FIG. 1). The flanges 2462 abut portions of the outer surface 2412 of the side door 24 that surround four sides of the slots 247, respectively. When the side door 24 is attached to or detached from the rack 23, the holding portions 2461 of the handles 246 can be accessed via the slots 247 and the openings 2463 to provide convenient attaching of the side door 24 to the rack 23 or convenient detaching of the side door 24 from the rack 23.

The brace 242 includes an elongated plate 2420, two side plates 2422 extending perpendicularly from left and right long sides of the elongated plate 2420, respectively, and two connecting strips 2424 extending perpendicularly outward from edges of the side plates 2422, respectively. The brace 242 is made of material having high intensity (strength), such as steel. The brace 242 is located at a middle portion of the inner surface 2410 of the main plate 241, and extends along a central longitudinal axis of the main plate 241. The elongated plate 2420 is substantially the same length as or slightly shorter than the main plate 241 of the side door 24. The brace 242 connects with the main plate 241 by the connecting strips 2424 being fixed to the inner surface 2410, with the elongated plate 2420 spaced from the inner surface 2410 of the main plate 241. In particular, a space 248 is defined between the elongated plate 2420 and the main plate 241. The brace 242 reinforces the side door 24, increasing a carrying capacity of the side door 24. In this embodiment, to ensure that the carrying capacity of the side door 24 is about 200 kilograms, the elongated plate 2420 of the brace 242 has a thickness of about 2.0 mm.

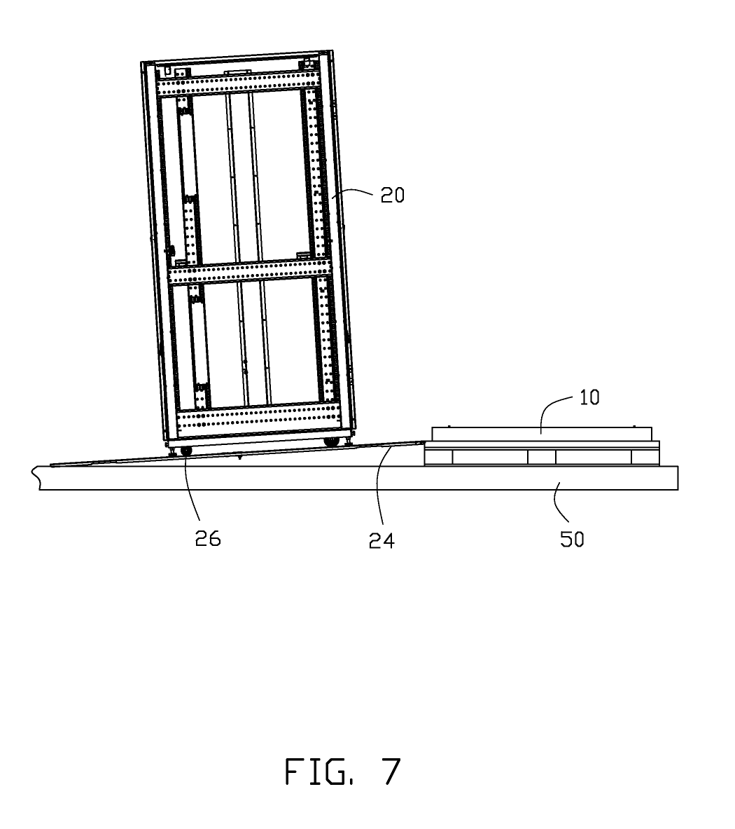

Referring back to FIG. 2, when the computer server system 20 is to be moved from the stack board 10 to another supporting area such as the ground 50, the side door 24 is detached from the server cabinet 21. The side door 24 is arranged between the stack board 10 and the ground 50, with one end of the side door 24 connected with one of the sides of the supporting plate 11 which does not have the restraining blocks 13. The inner surface 2410 of the main plate 241 together with the brace 242, the fasteners 244 and the handles 246 face the ground 50. A planar sloped surface between the side of the supporting plate 11 of the stack board 10 and the ground 50 is formed by the outer surface 2412 of the main plate 241. Finally, referring to FIG. 7, the computer server system 20 is pushed to the outer surface 2412 of the main plate 241, and moved downward to the ground 50 along the outer surface 2412 of the main plate 241. After the computer server system 20 reaches the ground 50, the side door 24 is reattached to the server cabinet 21.

The brace 242 formed at the inner surface 2410 of the side door 24 reinforces the side door 24, with the carrying capacity of the side door 24 thereby greatly increased. The side door 24 can be detached from the server cabinet 21 and positioned between two surfaces having different elevations, thereby functioning as a guiding ramp for secure relocation of the computer server system 20. Accordingly, there is no need to furnish a separate, dedicated guiding ramp. Thus, the server cabinet 21 provides convenient transportation and lowers costs.

It is to be understood, however, that even though numerous characteristics and advantages of the disclosure have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A server cabinet comprising:
a rack comprising a top wall, an opposite bottom wall, and a plurality of sidewalls connected between the top and bottom walls, the rack adapted to accommodate a plurality of servers; and
a side door detachably connected with the rack, the side door comprising a reinforcing brace such that when the rack is fully loaded with the servers and the side door is detached from the rack and positioned at an oblique angle between two surfaces capable of supporting the fully loaded server cabinet, the fully loaded server cabinet can be moved along the side door between the two surfaces.

2. The server cabinet of claim 1, wherein the brace comprises an elongated plate located at a middle portion of the side door and extending along a central longitudinal axis of the side door.

3. The server cabinet of claim 2, wherein the brace further comprises a plurality of side plates extending downwardly from long sides of the elongated plate and a plurality of connecting strips extending outwardly from edges of the side plates, respectively, the connecting strips being fixed to the side door, the elongated plate spaced from the side door to form a space therebetween.

4. The server cabinet of claim 2, wherein the brace is substantially the same length as the side door

5. The server cabinet of claim 1, further comprising a supporting frame received in the rack and a plurality of latch hooks mounted on the supporting frame, the side door comprising a plurality of fasteners configured for engagingly receiving the latch hooks, respectively.

6. The server cabinet of claim 5, wherein each of the latch hooks comprises a main body, a first flange connected with the supporting frame, and a second flange adjacent to the side door, the first and second flanges being at opposite sides of the main body, each of the fasteners comprising a mounting portion connected with the side door and a bent fastening catch rotatable with respect to the mounting portion, the fastening catch being rotatable between a first position engaged with the second flange and a second position disengaged from the second flange.

7. The server cabinet of claim 5, wherein the supporting frame comprises a plurality of supporting posts located adjacent to the side door, each of the supporting posts interconnected between the top and bottom walls, the latch hooks connected with the supporting posts, respectively.

8. The server cabinet of claim 1, wherein the side door comprises a plurality of recessed handles, each handle comprising a recessed holding portion defining an opening at a front side thereof and a frame-shaped flange extending around a periphery of the opening, the side door defining a plurality of slots corresponding to the handles, respectively, the openings of the handles communicated with the slots, respectively, and the flange-shaped flange abutting portions of an outer surface of the side door around the slots.

9. A server cabinet comprising:
a hollow cuboid rack adapted to hold a computer server system comprising a plurality of servers; and
a side door detachably connected with one side of the rack, the side door having a first major side and an opposite second major side, the side door comprising a reinforcing brace at the first side such that when the rack holds the computer server system and the side door is detached from the rack to obliquely interconnect two surfaces of two different levels, the server cabinet with the computer server system can be moved between the two surfaces along the second side of the side door.

10. The server cabinet of claim 9, wherein the brace comprise an elongated plate spaced from the first side of the side door, a plurality of side plates extending perpendicularly from sides of the elongated plate and a plurality of connecting strips extending perpendicularly outward from edges of the side plates, respectively, the connecting strips connected with the first side of the side door.

11. The server cabinet of claim 10, wherein the elongated plate extends along a central longitudinal axis of the side door.

12. The server cabinet of claim 10, wherein the brace is substantially the same length as the side door.

13. The server cabinet of claim 9, further comprising a supporting frame received in the rack and a plurality of latch hooks mounted on the supporting frame, each of the latch hooks comprising a second flange adjacent to the first side of the side door, the side door comprising a plurality of fasteners configured for engagingly the latch hooks, respectively, each of the fasteners comprising a mounting portion connected with the side door and a bent fastening catch rotatable with respect to the mounting portion, the fastening catch being rotatable between a first position engaged with the second flange and a second position disengaged from the second flange.

14. The server cabinet of claim 9, wherein the side door comprises a plurality of recessed handles, each handle comprising a recessed holding portion defining an opening at a front side thereof and an flange-shaped flange extending around a periphery of the opening, the side door defining a plurality of slots corresponding to the handles, respectively, the openings of the handles communicated with the slots, respectively, and the flange-shaped flange abutting portions of the second side of the side door around the slots.

15. A server cabinet comprising:
a rack adapted to accommodate a predetermined maximum plurality of servers; and
a side door detachably attached to the rack, the side door comprising a reinforcing brace such that the side door when detached from the rack to act as a ramp is capable of supporting the combined weight of the server cabinet plus the maximum plurality of servers but without the side door.

16. The server cabinet of claim 15, wherein the brace comprises an elongated plate extending along a longitudinal axis of the side door, two side plates extending perpendicularly from two long sides of the elongated plate, respectively, and two connecting strips extending outwardly from edges of the side plates, respectively, the connecting strips being fixed to the side door, the elongated plate spaced from the side door.

17. The server cabinet of claim 16, wherein the brace is substantially the same length as the side door.
